(19) United States
(12) Patent Application Publication
(10) Pub. No.: US 2017/0077190 A1
(43) Pub. Date: Mar. 16, 2017

(54) ORGANIC EL DISPLAY PANEL AND ORGANIC EL DISPLAY DEVICE

(71) Applicant: JOLED INC., Tokyo (JP)

(72) Inventors: Jun HASHIMOTO, Tokyo (JP); Hirotaka NANNO, Tokyo (JP); Masakazu TAKATA, Tokyo (JP); Toshiyuki AKIYAMA, Tokyo (JP)

(73) Assignee: JOLED INC., Tokyo (JP)

(21) Appl. No.: 15/309,232

(22) PCT Filed: May 21, 2015
(86) PCT No.: PCT/JP2015/002562

§ 371 Date: Nov. 7, 2016

(30) Foreign Application Priority Data
May 23, 2014 (JP) 2014-107376

(51) Int. Cl. H01L 27/32; H01L 51/56; G09F 9/30

(52) U.S. Cl. CPC H01L 27/3213; G09F 9/30; H01L 51/56; H01L 27/322

(57) ABSTRACT

Pixels include red sub-pixels, green sub-pixels, first blue sub-pixels that emit dark blue light, and second blue sub-pixels that emit light blue light. Above a substrate, first blue pixel electrodes and first blue organic light-emitting layers are layered in regions of the first blue sub-pixels and second blue pixel electrodes and second blue organic light-emitting layers are layered in regions of the second blue sub-pixels. The first blue light-emitting layers and the second blue light-emitting layers are made from the same material. In a direction perpendicular to a top plane of the substrate, a distance between top surfaces of the first blue organic light-emitting layers and top surfaces of the first blue pixel electrodes is less than a distance between top surfaces of the second blue organic light-emitting layers and the surfaces of the second blue pixel electrodes.

### TECHNICAL FIELD

The present invention relates to organic electroluminescence (EL) elements that use electroluminescence of organic material, organic EL display devices that use the organic EL elements, and in particular to techniques for improving the lifespan of display panels.

### BACKGROUND ART

In recent years, as display panels used in display devices such as televisions, panels have been implemented in which a plurality of organic light-emitting elements are arranged in a matrix on a substrate, using organic EL elements (hereinafter, “organic EL display panels”).

In an organic EL display panel, red, green, and blue organic EL elements form sub-pixels and combinations of red, green, and blue sub-pixels that are next to one another form single pixels. For this organic EL display panel, blue organic EL elements have the shortest lifespan among red, green, and blue organic EL elements, and improving lifespan of blue organic EL elements becomes a technical problem for improving light emission efficiency and lifespan of organic EL elements.

Addressing this technical problem, for example, Patent Literature 1 proposes an organic EL display panel including two blue sub-pixels for each red sub-pixel and green sub-pixel. Structures of the two sub-pixels are identical aside from the color filter. By making the color filter different, blue light having different y values in a CIExy color coordinate system is extracted from the two blue sub-pixels. According to Patent Literature 1, color representation in the blue direction is expanded by the blue sub-pixel having a low y value, light extraction efficiency of the color filter is increased for the blue sub-pixel having a high y value, and selecting to use two blue sub-pixels increases color reproducibility while suppressing power consumption and thereby achieving an increase in lifespan of the light-emitting elements.

### CITATION LIST

### Patent Literature

[Patent Literature 1] JP 2008-225179

### SUMMARY OF INVENTION

### Technical Problem

According to the configuration described above, a color filter is provided at a light extraction side of at least one of the two blue pixels to extract blue light having different y values in the CIExy color coordinate system from the two blue pixels, and therefore light emission efficiency from the dark blue sub-pixel having the low y value and from the light blue sub-pixel having the high y value does not increase, and this becomes an impediment to further improvement of light emission efficiency and lifespan of organic EL elements.

In view of the above technical problem, the present invention aims to provide an organic EL display panel that contributes to improved light emission efficiency and lifespan of the organic EL display panel, as well as an organic EL display device using the organic EL display panel.

### Solution to Problem

An organic electroluminescence (EL) display panel pertaining to one aspect of the present invention is an organic EL display panel in which a plurality of pixels are arranged in a matrix of rows and columns on a substrate, each pixel including a red sub-pixel that emits red light, a green sub-pixel that emits green light, a first blue sub-pixel that emits dark blue light, and a second blue sub-pixel that emits light blue light, the organic EL display panel comprising: the substrate; a first blue pixel electrode and a first blue organic light-emitting layer layered above the substrate in a region of the first blue sub-pixel; and a second blue pixel electrode and a second blue organic light-emitting layer layered above the substrate in a region of the second blue sub-pixel, wherein the first blue organic light-emitting layer and the second blue organic light-emitting layer are made from the same material, and in a direction perpendicular to a top plane of the substrate, a distance between a top surface of the first blue organic light-emitting layer and a top surface of the first blue pixel electrode is less than a distance between a top surface of the second blue organic light-emitting layer and a top surface of the second blue pixel electrode.

### Advantageous Effects of Invention

According to the organic EL display panel pertaining to the above aspect, an optical path length difference between direct light and reflected light emitted from organic light-emitting layers is made to be different between first sub-pixels and second sub-pixels, and therefore color emitted from organic light-emitting layers of the sub-pixels is made to be different. Thus, pixel light emission efficiency can be improved. This allows improved light emission efficiency and improved life of organic EL elements when compared to conventional technology.

### BRIEF DESCRIPTION OF DRAWINGS

FIG. 1 is a schematic block diagram showing configuration of a display device 1 pertaining to Embodiment 1.

FIG. 2 is a schematic circuit diagram showing a circuit configuration of each sub-pixel 10a of an organic EL display panel used in the display device 1.

FIG. 3 is a schematic plan view showing a portion of an organic EL display panel pertaining to Embodiment 1.

FIG. 4 is a schematic cross-section through A-A in FIG. 3.

FIG. 5 is a schematic cross-section through B-B in FIG. 3.

FIG. 6A, FIG. 6B, FIG. 6C, and FIG. 6D are schematic cross-sections through A-A showing processes in manufacturing the organic EL display panel.

FIG. 7A, FIG. 7B, FIG. 7C, FIG. 7D, and FIG. 7E are schematic cross-sections through B-B showing processes in manufacturing the organic EL display panel.

FIG. 8 is a schematic diagram showing direct light C1 and reflected light C2 in an optical resonator structure formed in a panel 10.

FIG. 9 shows a relationship between colors of light emitted and light emission efficiency of sub-pixels of second blue sub-pixels 21LB.

FIG. 10 shows color reproduction ranges of the display device 1 in a CIE chromaticity diagram.

### EMBODIMENT

### Summary of Aspects of Present Invention

An organic electroluminescence (EL) display panel pertaining to one aspect of the present invention is an organic EL display panel in which a plurality of pixels are arranged in a matrix of rows and columns on a substrate, each pixel including a red sub-pixel that emits red light, a green sub-pixel that emits green light, a first blue sub-pixel that emits dark blue light, and a second blue sub-pixel that emits light blue light, the organic EL display panel comprising: the substrate; a first blue pixel electrode and a first blue organic light-emitting layer layered above the substrate in a region of the first blue sub-pixel; and a second blue pixel electrode and a second blue organic light-emitting layer layered above the substrate in a region of the second blue sub-pixel, wherein the first blue organic light-emitting layer and the second blue organic light-emitting layer are made from the same material, and in a direction perpendicular to a top plane of the substrate, a distance between a top surface of the first blue organic light-emitting layer and a top surface of the first blue pixel electrode is less than a distance between a top surface of the second blue organic light-emitting layer and a top surface of the second blue pixel electrode.

According to another example, thickness of the first blue organic light-emitting layer is less than thickness of the second blue organic light-emitting layer.

According to another example, thickness of the first blue organic light-emitting layer is less than 45 nm and thickness of the second blue organic light-emitting layer is from 45 nm to 65 nm.

According to another example, a y value of CIE chromaticity of light emitted from the first blue sub-pixel is less than a y value of CIE chromaticity of light emitted from the second blue sub-pixel.

According to another example, a first filter that lowers a y value of CIE chromaticity of light emitted from the first blue organic light-emitting layer is disposed above the first blue organic light-emitting layer.

According to another example, a second filter that has a higher transmittance of light in a wavelength range from 600 nm to 800 nm than the first filter is disposed above the second blue organic light-emitting layer.

According to another example, transmittance of light in a wavelength range from 300 nm to 800 nm by the first filter is 0.5 or less and transmittance of light in the wavelength range from 300 nm to 800 nm by the second filter is 0.7 or greater.

According to another example, a y value of CIE chromaticity of light emitted upwards from the first filter in the first blue sub-pixel is less than a y value of CIE chromaticity of light emitted upwards from the second filter in the second blue sub-pixel.

According to another example, a y value of CIE chromaticity of light emitted upwards from the first filter in the first blue sub-pixel is less than 0.1 and a y value of CIE chromaticity of light emitted upwards from the second filter in the second blue sub-pixel is from 0.1 to 0.18.

A method of manufacturing an organic electroluminescence (EL) display panel pertaining to an aspect of the present invention is a method of manufacturing an organic EL display panel in which a plurality of pixels are arranged in a matrix of rows and columns, each pixel including a red sub-pixel that emits red light, a green sub-pixel that emits green light, a first blue sub-pixel that emits dark blue light, and a second blue sub-pixel that emits light blue light, the method comprising: a process of forming a first blue pixel electrode and a first blue organic light-emitting layer layered in this order above the substrate in a region of the first blue sub-pixel, and forming a second blue pixel electrode and a second blue organic light-emitting layer layered in this order above the substrate in a region of the second blue sub-pixel, wherein in the process of forming the first blue organic light-emitting layer and the second blue organic light-emitting layer, in a direction perpendicular to the plane of the substrate, a distance between a top surface of the first blue organic light-emitting layer and a top surface of the first blue pixel electrode is made to be less than a distance between a top surface of the second blue organic light-emitting layer and a top surface of the second blue pixel electrode layer.

Note that in the present application, “above”, “top”, and “upper” do not refer to an upwards (vertical) direction in absolute spatial awareness, but define relative positional relationships based on an order of layering. Further, “above” is not limited to indicating a relationship between two elements in which a gap is present therebetween, and may be applied when the two elements are in direct contact.

### Embodiment 1

### 1. Configuration of Display Device 1

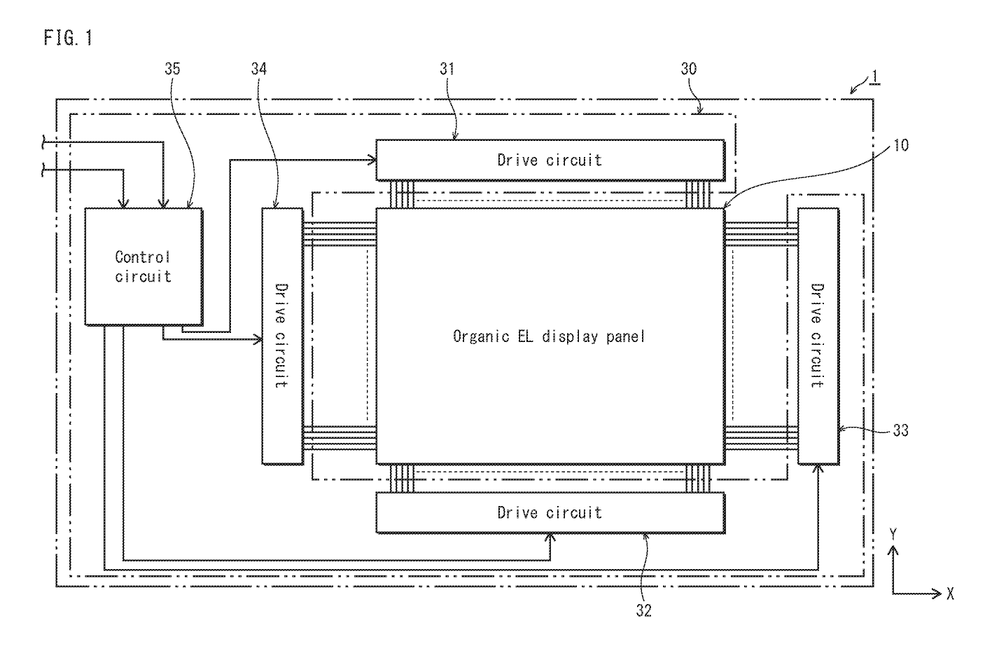

The following describes overall configuration of a display device 1 pertaining to Embodiment 1, with reference to FIG. 1.

As shown in FIG. 1, the display device 1 pertaining to the present embodiment includes an organic EL display panel 10 and drive/control circuitry 30 connected thereto.

The organic EL display panel 10 is an organic electroluminescence (EL) panel that uses electroluminescence of organic material, in which a plurality of organic EL elements are, for example, arranged in a matrix. The drive/control circuitry 30 includes four drive circuits 31, 32, 33, 34 and a control circuit 35.

In the display device 1, the arrangement of the circuits of the drive/control circuitry 30 relative to the organic EL display panel 10 is not limited to the example shown in FIG. 1.

### 2. Circuit Configuration in the Organic EL Display Panel 10

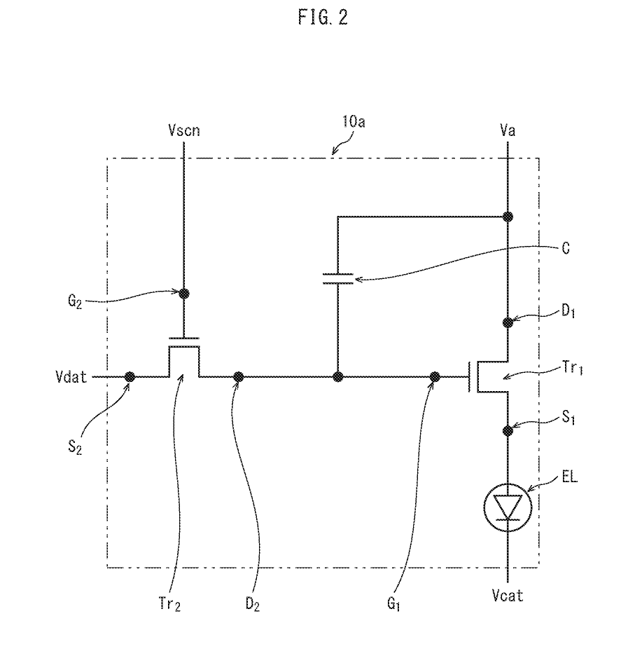

The following describes circuit configuration of each pixel 10a in the organic EL display panel 10, with reference to FIG. 2.

As shown in FIG. 2, according to the organic EL display panel 10 pertaining to the present embodiment, each sub-pixel 10a includes a transistor Tr₁, a transistor Tr₂, a capacitor C, and an EL element EL as a light emitter. The transistor Tr₁ is a drive transistor Tr₁ and the transistor Tr₂ is a switching transistor Tr₂.

A gate G₂ of the switching transistor Tr₂ is connected to a scanning line Vscn and a source S₂ of the switching transistor Tr₂ is connected to a data line Vdat. A drain D₂ of the switching transistor Tr₂ is connected to a gate G₁ of the drive transistor Tr₁.

A drain D₁ of the drive transistor Tr₁ is connected to a power supply line Va and a source S₁ of the drive transistor Tr₁ is connected to an anode of the EL element EL. A cathode of the EL element EL is connected to a ground line Vcat.

The capacitor C connects the drain D₂ of the switching transistor Tr₂, the gate G₁ of the drive transistor Tr₁, and the power supply line Va.

In the organic EL display panel 10, a pixel includes one set of sub-pixels 10a that are adjacent to one another (for example, red (R), green (G), dark blue (DB), and light blue (LB) sub-pixels 10a), and each pixel is arranged in a matrix to form a pixel region. Each gate line GL extends from a gate G₂ of a pixel arranged in the matrix, and is connected to a scanning line Vscn that is connected from outside the organic EL display panel 10. Similarly, each source line SL extends from a source S₂ of a pixel and is connected to a data line Vdat that is connected from outside the organic EL display panel 10.

Further, power supply lines Va of pixels and ground lines Vcat of pixels are aggregated and connected to a power supply line Va and a ground line Vcat.

### 2. Configuration of Organic EL Display Panel 10

The organic EL display panel 10 pertaining to Embodiment 1, which is an aspect of the present invention, is described below with reference to the drawings. The drawings are schematic, and dimensions may differ from actual implementation.

<Overall Configuration>

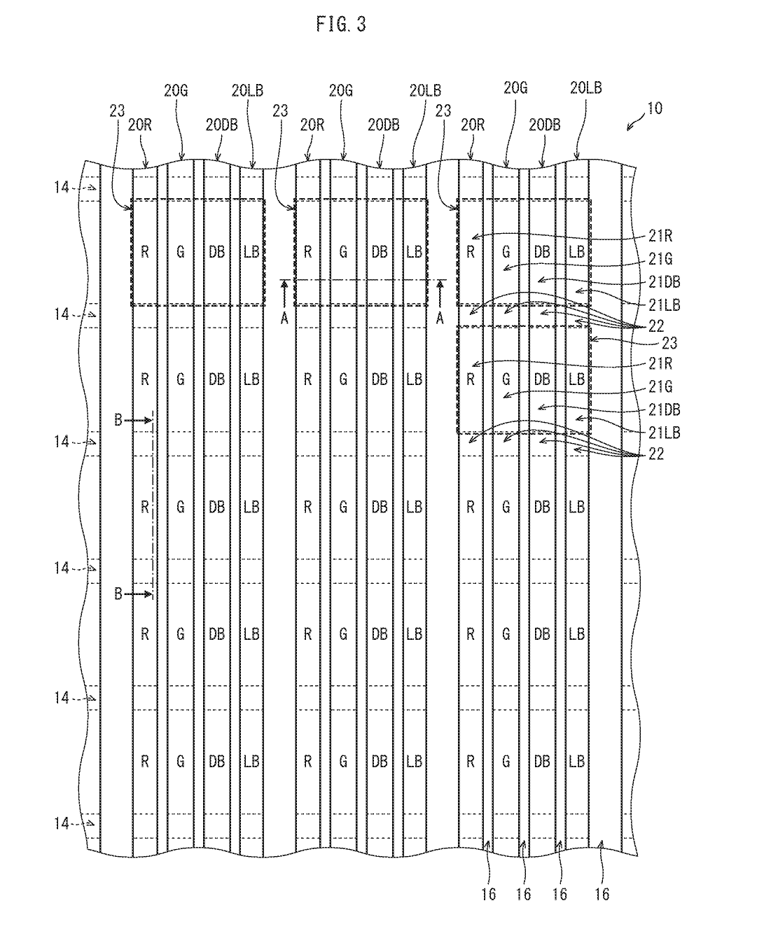

FIG. 3 is a schematic plan view showing a portion of an organic EL display panel pertaining to Embodiment 1. As shown in FIG. 3, the organic EL display panel 10 (hereinafter, “panel 10”) is an organic EL display panel that uses electroluminescence of organic compounds. According to the panel 10, line banks are used, a plurality of first banks 16 extending in a column direction (the longitudinal direction of the drawing in FIG. 3). Further, where intervals 20 are defined between adjacent ones of the first banks 16, the panel 10 has a configuration in which the first banks 16 and the intervals 20 alternate.

In each of the intervals 20, a plurality of sub-pixels 21 and a plurality of inter-pixel regions 22 between adjacent ones of the sub-pixel 21 alternate in the column direction. Each of the sub-pixels 21 corresponds to the example of the sub-pixels 10a in FIG. 2. Further, in the inter-pixel regions 22 in the intervals 20 are second banks 14 that extend in a row direction (the lateral direction of the drawing in FIG. 3). The first banks 16 in the column direction and the second banks 14 in the row direction are orthogonal.

According to the present embodiment, the sub-pixels 21 are further classified as red sub-pixels 21R that emit red light, green sub-pixels 21G that emit green light, first blue sub-pixels 21DB that emit dark blue light, and second blue sub-pixels 21LB that emit light blue light (where no distinction is made between 21R, 21G, 21DB, 21LB, they are referred to as “sub-pixels 21”). The intervals 20 are further classified as red intervals 20R in which are the red sub-pixels 21R, green intervals 20G in which are the green sub-pixels 21G, first blue intervals 20DB in which are the first blue sub-pixels 21DB, and second blue intervals 20LB in which are the second blue sub-pixels 21LB (where no distinction is made between 20R, 20G, 20DB, 20LB, they are referred to as “intervals 21”). Further, four of the sub-pixels 21, i.e., one of the red sub-pixels 21R, one of the green sub-pixels 21G, one of the first blue sub-pixels 21DB, and one of the second blue sub-pixels 21LB, are lined up in the row direction to form one pixel 23.

Edges of the sub-pixels 21 in the column direction are defined by the second banks 14, as described later. The second banks 14 are disposed in the same position in the column direction for each color of the sub-pixels 21. Further, edges of the sub-pixels 21 in the row direction are defined by edges in the row direction of organic light-emitting layers, as described later. The edges in the row direction of the organic light-emitting layers are defined by the first banks 16.

<Configuration>

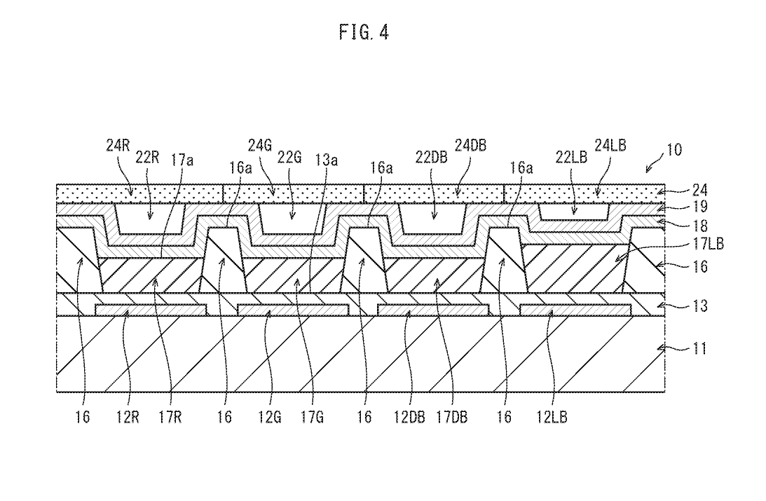

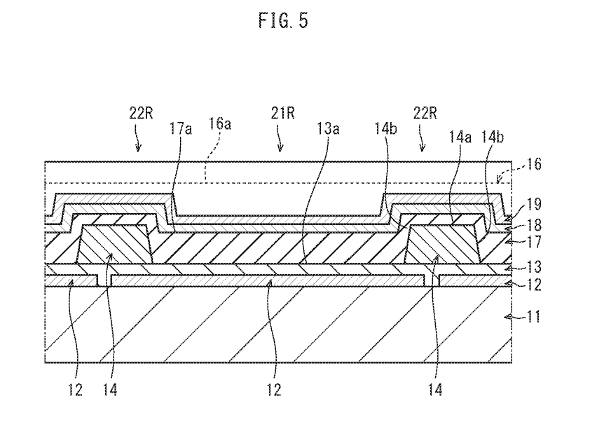

The following describes configuration of the panel 10, with reference to FIG. 4 and FIG. 5. FIG. 4 is a schematic cross-section through A-A in FIG. 3. FIG. 5 is a schematic cross-section through B-B in FIG. 3.

The panel 10, as one example, has a display surface facing a “top side” of the drawings in FIG. 4 and FIG. 5, and is a top-emission type of panel. In the following description, the “top side” of the drawings in FIG. 4 and FIG. 5 is described as the top side of the panel 10.

The panel 10 includes a substrate 11, pixel electrodes 12, a base layer 13, second banks 14, first banks 16, light-emitting layers 17, an opposing electrode 18, and a sealing layer 19.

(1) Substrate

The substrate 11 has a base material (not illustrated), a thin film transistor (TFT) layer (not illustrated) disposed on the base material, and an interlayer insulating layer (not illustrated) disposed on the base material and the TFT layer.

The base material is a supporting material of the panel 10 and is flat. As a material of the base material a material that is electrically insulative can be used, such as a glass material, a resin material, a semiconductor material, or a metal material coated with an insulating layer.

The TFT layer includes a plurality of TFTs and circuitry disposed on a top surface of the base material. Each TFT responds to a drive signal from circuitry external to the panel 10, is electrically connected to a corresponding one of the pixel electrodes 12 and an external power source, and has a layered structure including an electrode, a semiconductor layer, an insulating layer, etc. The circuitry is electrically connected to the TFTs, the pixel electrodes 12, the external power source, the external circuitry, etc.

The interlayer insulating layer planarizes a top surface of the substrate 11 where unevenness is caused by the TFT layer, at least in regions of the sub-pixels 21. Further, the interlayer insulating layer fills between the circuitry and the TFTs, electrically insulating between the circuitry and the TFTs. As a material of the interlayer insulating layer, a positive photosensitive organic material that is electrically insulative can be used, such as acrylic resin, polyimide resin, siloxane resin, or phenolic resin.

(2) Pixel Electrodes

On the substrate 11, red pixel electrodes 12R are disposed in regions of the red sub-pixels 21R, green pixel electrodes 12G are disposed in regions of the green sub-pixels 21G, first blue pixel electrodes 12DB are disposed in regions of the first blue sub-pixels 21DB, and second blue pixel electrodes 12LB are disposed in regions of the second blue sub-pixels 21LB (where no distinction is made between the red pixel electrodes 12R, the green pixel electrodes 12G, the first blue pixel electrodes 12DB, and the second blue pixel electrodes 12LB they are referred to as “pixel electrodes 12”). The pixel electrodes 12 supply carriers to the light-emitting layers 17, for example when functioning as anodes they supply holes to the light-emitting layers 17. Each of the pixel electrodes 12 is flat, but, for example, when connection to the TFTs is via contact holes opened in the interlayer insulating layer, each of the pixel electrodes 12 has an uneven shape following the shape of a corresponding contact hole. The pixel electrodes 12 are disposed on the substrate 11 in the intervals 20, spaced from each other in the column direction.

As a material of the pixel electrodes 12, because the panel 10 is a top-emission type, a light-reflective electrically conductive material is preferred, such as a metal like silver, aluminium, or molybdenum, or an alloy thereof.

(3) Base Layer

The base layer 13 is, for example, a hole injection layer in the present embodiment, and is a continuous solid film above the pixel electrodes 12. When the base layer 13 is formed as a continuous solid film, the manufacturing process is simplified.

Further, the base layer 13 includes a transition metal oxide and functions as a hole injection layer. Here, a transition metal is an element in any group from group 3 to group 11 of the Periodic Table. Among transition metals, transition metals such as tungsten, molybdenum, nickel, titanium, vanadium, chromium, manganese, iron, cobalt, niobium, hafnium, or tantalum are preferred, as they have good hole injection properties after oxidization. In particular, tungsten is suitable for forming a hole injection layer having good hole injection properties. However, the base layer 13 is not limited to being formed from a transition metal oxide, and may for example be an alloy of a transition metal of an oxide other than a transition metal oxide. Further, the base layer 13 is not limited to being a hole injection layer and may be any kind of layer disposed between the pixel electrodes 12 and the light-emitting layers 17.

(4) Second Banks

The second banks 14 control flow of ink in the column direction, the ink being used in forming the light-emitting layers 17 and containing an organic compound that is a material of the light-emitting layers 17. The second banks 14 are present above peripheral portions in the column direction of the pixel electrodes 12 and are formed partially overlapping the pixel electrodes 12 in plan view. Thus, the second banks 14 define edges of the sub-pixels 21 in the column direction. Each of the second banks 14 is elongated in the row direction. In cross-section in the column direction, each of the second banks 14 has a tapered trapezoidal shape that tapers upwards. The second banks 14 extend in the row direction, orthogonal to the column direction, and pass through the first banks 16. Each of the second banks 14 has a top surface 14a that is lower than a top surface 16a of each of the first banks 16.

As a material of the second banks 14, an electrically insulative material is used such as an inorganic material or an organic material. The inorganic material may be silicon oxide or silicon nitride, for example. The organic material may be an acrylic resin, a polyimide resin, a siloxane resin, or a phenolic resin, for example.

(5) First Banks

The first banks 16 control flow of ink in the row direction when forming the light-emitting layers 17 in the intervals 20. The first banks 16 are present above peripheral portions in the row direction of the pixel electrodes 12 and are formed partially overlapping the pixel electrodes 12 in plan view. Thus, the first banks 16 define edges of the sub-pixels 21 in the row direction. Each of the first banks 16 is elongated in the column direction. In cross-section in the row direction, each of the first banks 16 has a tapered trapezoidal shape that tapers upwards. The first banks 16 are disposed on the base layer 13, sandwiching the pixel electrodes 12 in the row direction and passing over the second banks 14.

As a material of the first banks 16, an organic material such as an acrylic resin, a polyimide resin, a siloxane resin, or a phenolic resin can be used, for example. The first banks 16 are preferably formed from a material that is resistant to organic solvents and does not excessively deform or alter in response to etching and baking processes. Further, in order to impart liquid repellency to surfaces of the first banks 16, the surfaces may be fluorine-treated.

(6) Light-Emitting Layers

Above the substrate 11, red organic light-emitting layers 17R are above the red pixel electrodes 12R in the red sub-pixels 21R, green organic light-emitting layers 17G are above the green pixel electrodes 12G in the green sub-pixels 21G, first blue organic light-emitting layers 17DB are above the first blue pixel electrodes 12DB in the first blue sub-pixels 21DB, and second blue organic light-emitting layers 17LB are above the second blue pixel electrodes 12LB in the second blue sub-pixels 21LB (where no distinction is made between the red organic light-emitting layers 17R, the green organic light-emitting layers 17G, the first blue organic light-emitting layers 17DB, and the second blue organic light-emitting layers 17LB, they are referred to as “light-emitting layers 17”). The light-emitting layers 17 are layers that include an organic compound and have a function of emitting light by recombination of holes and electrons therein. Each of the light-emitting layers 17 extends in the column direction in one of the intervals 20 and is disposed on a top surface 13a of the base layer 13 in the sub-pixels 21 and on the top surfaces 14a and side surfaces 14b of the second banks 14 in the inter-pixel regions 22.

Only the portions of the light-emitting layers 17 that are supplied carriers from the pixel electrodes 12 emit light. Accordingly, as shown in FIG. 3, only the portions of the light-emitting layers 17 in the sub-pixels 21 over the pixel electrodes 12 emit light, and the portions of the inter-pixel regions 22 on the second banks 14 do not emit light.

As shown in FIG. 3, the light-emitting layers 17 are not only present in the sub-pixels 21 but extend to adjacent ones of the inter-pixel regions 22. Thus, when forming the light-emitting layers 17, ink applied to the sub-pixels 21 can flow in the column direction via ink applied to the inter-pixel regions 22 and film thickness is equalized between the sub-pixels 21 in the column direction. However, in the inter-pixel regions 22, flow of ink is suppressed to an appropriate level by the second banks 14. Accordingly, significant irregularity in film thickness in the column direction is unlikely.

As a material of the light-emitting layers 17, an organic material with light-emitting properties that can form a thin film by a wet process is used. For example, a compound, derivative, or complex of a fluorescent material is used, such as an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, metal complex of an 8-hydroxyquinoline compound, metal complex of a 2-bipyridine compound, complex of a Schiff base and a group III metal, metal complex of oxine, rare earth complex, or similar (all disclosed in JP H5-163488), or a publicly-known fluorescent material or phosphorescent material is used.

The first blue organic light-emitting layers 17DB and the second organic light-emitting layers 17LB are preferably made from the same material. Further, in such a case, thickness of the first blue organic light-emitting layers 17DB are preferably less than thickness of the second blue organic light-emitting layers 17LB. For example, the thickness of the second blue organic light-emitting layers 17LB is from 45 nm to 65 nm while the thickness of the first blue organic light-emitting layers 17DB is less than 45 nm.

(7) Opposing Electrode

The opposing electrode 18 is disposed above the red organic light-emitting layers 17R, the green organic light-emitting layers 17G, the first blue organic light-emitting layers 17DB, and the second blue organic light-emitting layers 17LB, and opposes the red pixel electrodes 12R in regions of the red sub-pixels 21R, the green pixel electrodes 12G in regions of the green sub-pixels 21G, the first blue pixel electrodes 12DB in regions of the first blue-pixels 21DB, and the second blue pixel electrodes 12LB in regions of the second blue sub-pixels 21LB. The opposing electrode 18 opposes the pixel electrodes 12, forming conductive paths by sandwiching the light-emitting layers 17. The opposing electrode 18 supplies carriers to the light-emitting layers 17, for example when functioning as a cathode it supplies electrons to the light-emitting layers 17. The opposing electrode 18 follows top surfaces 17a of the light-emitting layers 17 and surfaces of the first banks 16 that are exposed from the light-emitting layers 17, forming an electrode common to all the light-emitting layers 17.

As a material of the opposing electrode 18, a light-transmissive electrically-conductive material is used, because the panel 10 is a top-emission type. For example, indium tin oxide (ITO) or indium zinc oxide (IZO) can be used.

(8) Sealing Layer

The sealing layer 19 suppresses degradation of the light-emitting layers 17 due to contact with moisture and air. The sealing layer 19 spans a face of the panel 10, covering a top surface of the opposing electrode 18. As a material of the sealing layer 19, a light-transmissive material is used, such as silicon nitride or silicon oxynitride, because the panel 10 is a top-emission type.

(9) Color Filter, Other

Although not illustrated in FIG. 2 or FIG. 3, a color filter and upper substrate may be joined to the sealing layer 19. Thus, display colors of the panel 10 can be adjusted, stiffness enhanced, and protection from penetration of moisture and air can be provided.

The color filter includes red filters 24R, green filters 24G, first blue filters 24DB that are dark blue filters, and second blue filters 24LB that are light blue filters, disposed above the red intervals 20R, which are regions of the red sub-pixels 21R, the green intervals 20G, which are regions of the green sub-pixels 21G, the first blue intervals 20DB, which are regions of the first blue sub-pixels 21DB, and the second blue intervals 20LB, which are regions of the second blue intervals 21LB.

The color filters 24B, 24G, 24DB, 24LB are light-transmissive layers provided to allow transmission of wavelengths of visible light corresponding to red, green, dark blue, and light blue, and have a function of correcting chromaticity of light emitted from sub-pixels. The color filters 24G, 24R, 24DB, 24LB, for example, are formed by a process of applying ink containing color filter material and solvent to cover glass that is provided with banks in a matrix of rows and columns in which a plurality of openings are provided in units of the sub-pixels 21.

The second blue filters 24LB have a transmission ratio for wavelengths 600 nm to 800 nm that is higher than that of the first blue filters 24DB. For example, for wavelengths 600 nm to 800 nm, the transmission ratio of the first blue filters 24DB is preferably 0.5 or less and the transmission ratio of the second blue filters 24LB is preferably 0.7 or greater.

### 2. Organic EL Display Panel Manufacturing Method

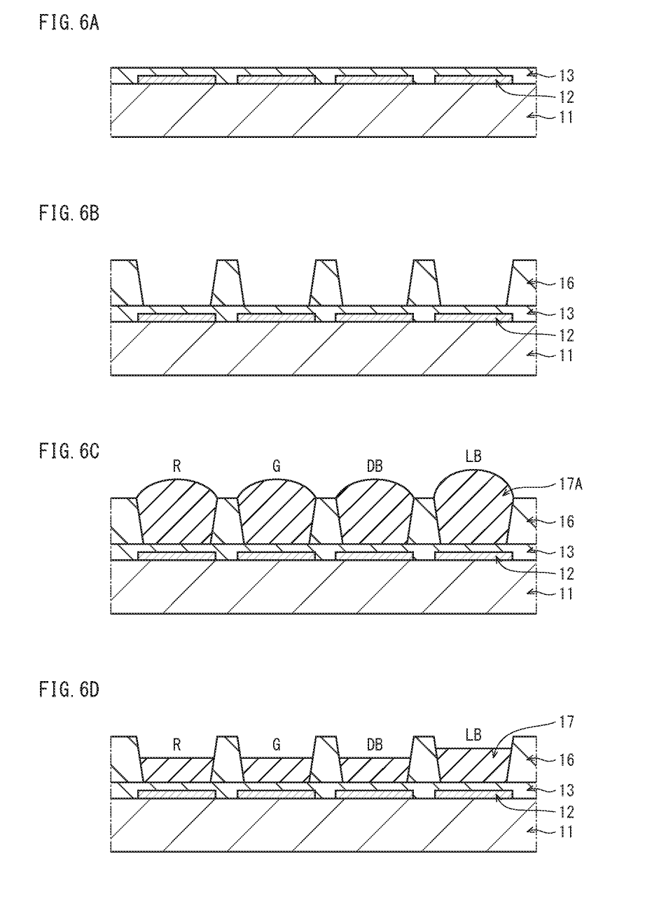

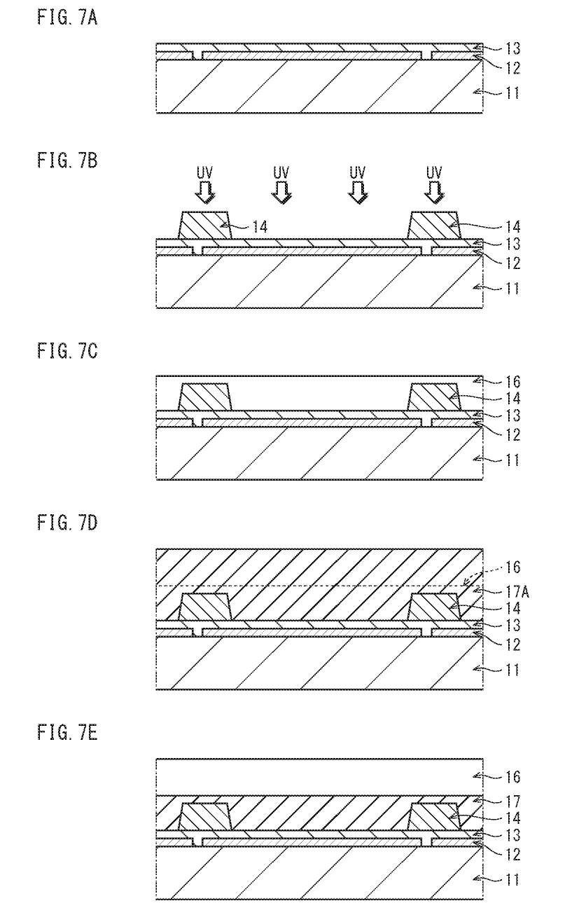

The following describes a method of manufacturing the panel 10, with reference to FIG. 6 and FIG. 7. FIG. 6A, FIG. 6B, FIG. 6C, and FIG. 6D are schematic cross-sections through A-A showing processes in manufacturing the organic EL display panel. FIG. 7A, FIG. 7B, FIG. 7C, FIG. 7D, and FIG. 7E are schematic cross-sections through B-B showing processes in manufacturing the organic EL display panel.

(1) Substrate Preparation Process

First, the substrate 11 is prepared. More specifically, for example, required layers are formed on the base material by a process such as sputtering, chemical vapor deposition (CVD), or spin coating, then patterning is performed by photolithography to form a TFT layer and an interlayer insulating layer. As required, plasma processing, ion injection, baking, etc., may be performed.

(2) Pixel Electrodes Formation Process

Subsequently, the pixel electrodes 12 are formed on the substrate 11. More specifically, for example, vacuum deposition or sputtering is used to form a metal film on the substrate 11. Subsequently, the metal film is patterned by photolithography, to form the pixel electrodes 12 at intervals on the substrate 11 in the column direction, and further columns of the pixel electrodes 12 are formed in parallel. In this way, the pixel electrodes 12 are formed in two dimensions on the substrate 11.

(3) Base Layer Formation Process

Subsequently, as shown in FIG. 6A and FIG. 7A, the base layer 13 is formed on the substrate 11 after formation of the pixel electrodes 12. More specifically, for example, a solid film oxide layer (base layer 13) is formed on the substrate 11, completely covering the pixel electrodes 12, by sputtering.

(4) Second Banks Formation Process

Subsequently, as shown in FIG. 7B, the second banks 14 are formed on the base layer 13. More specifically, for example, an inorganic insulating film (such as silicon oxide) is formed on the base layer 13 by CVD. Subsequently, the inorganic insulating film is patterned by photolithography to form the second banks 14, which extend in the row direction and sandwich rows of the pixel electrodes 12.

After forming the second banks 14, the second banks 14 are irradiated from above by UV and then baked, in order to increase lyophilicity.

(5) First Banks Formation Process

Subsequently, as shown in FIG. 6B and FIG. 7C, the first banks 16 are formed on a portion of the base layer 13 and a portion of the second banks 14. More specifically, for example, a positive-type photosensitive organic material (such as acrylic resin) is applied by spin coating. At this time, film thickness of the material applied is greater than film thickness of the second banks 14. Subsequently, the photosensitive organic material is patterned by photolithography to form the first banks 16, which extend in the column direction and sandwich columns of the pixel electrodes 12.

Printing methods, etc., may alternatively be used to directly form the first banks 16. Further, the first banks 16 may be surface treated by alkaline solution, water, organic solvent, or plasma, to confer liquid repellency to surfaces of the first banks 16, the liquid repellency repelling ink applied in a subsequent process. In this way, in a subsequent light-emitting layer formation process, overflow of ink over the first banks 16 is suppressed.

Due to this process, the intervals 20 are formed between adjacent ones of the first banks 16, and columns of the pixels 21 and the inter-pixel regions 22 exist in the intervals 20.

(6) Light-Emitting Layer Formation Process

Subsequently, as shown in FIG. 6C and FIG. 7D, ink 17A is applied in the intervals 20. More specifically, for example, the ink 17A is formed from a mix of an organic compound that will become material of the light-emitting layers 17 and a solvent in a predefined ratio, and the ink 17A is applied in the intervals 20 by using an inkjet method. The ink 17A is applied so that top surfaces of the ink 17A are higher than the top surfaces 14a of the second banks 14, and therefore the ink 17A can flow over the second banks 14. Subsequently, solvent in the ink 17A is evaporated to dryness, thereby forming the light-emitting layers 17. As a method of applying the ink 17A, a dispenser method, nozzle-coating method, spin coating method, or printing method may alternatively be used. In order to prevent the light-emitting layers 17 being divided over the second banks 14, the ink 17A preferably has good wettability with respect to the surfaces of the second banks 14 (the top surfaces 14a and the side surfaces 14b).

Further, according to the present embodiment, the light-emitting layers 17 have the sub-pixels 21 in the four colors red, green, dark blue, and light blue, and therefore different versions of the ink 17A is used for each. More specifically, for example, four colors of the ink 17A may be applied in order using a nozzle that dispenses only the ink 17A corresponding to one of red, green, dark blue, or light blue, or four colors of the ink 17A may be applied simultaneously using four linked nozzles that simultaneously dispense the ink 17A in each of the four colors red, green, dark blue, and light blue.

According to the panel 10, the first blue organic light-emitting layers 17DB and the second organic light-emitting layers 17LB are preferably made from the same material. This is because simultaneously applying the ink 17A of the first blue organic light-emitting layers 17DB and the second blue organic light-emitting layers 17B simplifies manufacture and contributes to cost reduction. Further, an amount of ink applied to the first blue intervals 20DB can be controlled to be less than an amount of ink applied to the second blue intervals 20LB, and therefore thickness of the first blue organic light-emitting layers 17DB can be made to be less than thickness of the second blue organic light-emitting layers 17LB. In this case, film thickness of the second blue organic light-emitting layers 17LB is controlled by setting an amount of ink applied. The same is true for the first blue organic light-emitting layers 17DB.

Further, because the panel 10 uses line banks, a method of using an array of nozzles in the column direction that each dispense only the ink 17A of the same color while being moved in a direction orthogonal to the column direction to dispense the ink 17A into the intervals 20 to form the light-emitting layers 17 is preferable. According to this method, a plurality of nozzles are used, which shortens the process and the time to apply the ink 17A. Also, because the ink 17A dispensed from the plurality of nozzles is connected in the column direction in the intervals 20, even if an amount of the ink 17A dispensed from each nozzle varies, the ink 17A can flow in the column direction, which equalizes the amount applied, reducing film thickness unevenness and therefore luminance unevenness between the pixels 21.

When the ink 17A is dried, the light-emitting layers 17 are formed in the intervals 20, as shown in FIG. 6D and FIG. 7E. In the intervals 20 are formed the light-emitting layers 17 in the pixels 21 that exist where the second banks 14 do not cover the base layer 13 and across the inter-pixel regions 22 where the second banks 14 are present.

(7) Opposing Electrode Formation Process

Subsequently, the opposing electrode 18 is formed to follow the top surfaces 17a of the light-emitting layers 17 and surfaces of the first banks 16 that are exposed from the light-emitting layers 17. More specifically, for example, a film is formed that is made from a light-transmissive electrically-conductive material such as ITO or IZO, following the top surfaces 17a of the light-emitting layers 17 and surfaces of the first banks 16 that are exposed from the light-emitting layers 17, by a method such as vacuum deposition or sputtering.

(8) Sealing Layer Formation Method

Subsequently, the sealing layer 19 is formed covering a top surface of the opposing electrode 18. More specifically, for example, an inorganic insulating film (such as silicon oxide) is formed on the opposing electrode 18 by sputtering or CVD.

### 3. Configuration of Organic EL Display Panel

(1) Improving Light Emission Efficiency of Second Blue Sub-Pixels

In each color of the sub-pixels 21 a corresponding color of the light-emitting layers 17 exists between one of the pixel electrodes 12 and the opposing electrode 18. As described below, an optical resonator structure is formed in which light from the light-emitting layers 17 is made to resonate and be emitted from the opposing electrode. Light generated in the light-emitting layers 17 is emitted externally from the opposing electrode 18, but includes both “direct light” directly emitted from the light-emitting layers 17 towards the opposing electrode 18 and “reflected light” emitted from the light-emitting layers 17 towards the pixel electrodes 12 the reflected at the pixel electrodes 12 towards the opposing electrode 18.

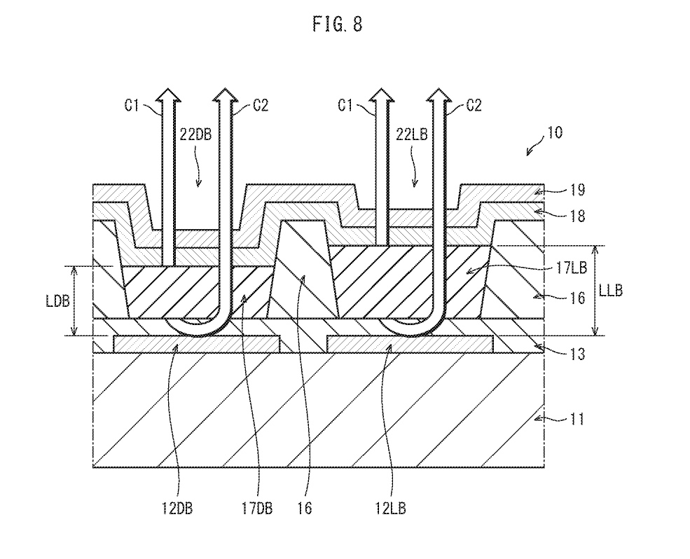

FIG. 8 is a diagram showing direct light and reflected light in an optical resonator structure in the panel 10. In FIG. 8, a blue element including blue light-emitting layers 17DB, 17LB is shown, but the same is true for red and green elements.

In an optical resonator structure of the panel 10, a portion of light emitted from the light-emitting layers 17 travels to the opposing electrode 18 without travelling to the pixel electrodes 12, and is emitted from the organic light-emitting element via the opposing electrode 18, and this is referred to as a first optical path C1; and a remaining portion of light emitted from the light-emitting layers 17 travels to the pixel electrodes 12, is reflected at the pixel electrodes, and is emitted from the organic light-emitting element via the light-emitting layers 17 and the opposing electrode 18, and this is referred to as a second optical path C2.

According to interference between the direct light and the reflected light, optical distances LDB, LLB are set between top surfaces of the light-emitting layers 17 and top surfaces of the pixel electrodes 12 so interference is constructive for light components corresponding to each color. More specifically, as stated above, thickness of the first blue organic light-emitting layers 17DB is less than thickness of the second blue organic light-emitting layers 17LB. For example, the thickness of the second blue organic light-emitting layers 17LB is from 45 nm to 65 nm while the thickness of the first blue organic light-emitting layers 17DB is less than 45 nm. Thus, optical distances between top surfaces of the light-emitting layers 17 and top surfaces of the pixel electrodes 12 are configured so the optical distance LDB in the first blue sub-pixels 21DB is less than the optical distance LLB in the second blue sub-pixels 21LB.

Thus, in the first blue sub-pixels 21DB and the second blue sub-pixels 21LB, a difference occurs in lengths of the first optical path C1 and the second optical path C2, and between the first blue sub-pixels 21DB and the second blue sub-pixels 21LB, a difference occurs in wavelengths of constructive light and wavelengths of destructive light due to direct light and reflected light interference. As a result, y values of CIE chromaticity of light emitted from the opposing electrode 18 from the first blue sub-pixels 21DB and the second blue sub-pixels 21LB have a property that a y value of CIE chromaticity of light emitted from the first blue sub-pixels 21DB is less than a y value of CIE chromaticity of light emitted from the second blue sub-pixels 21LB.

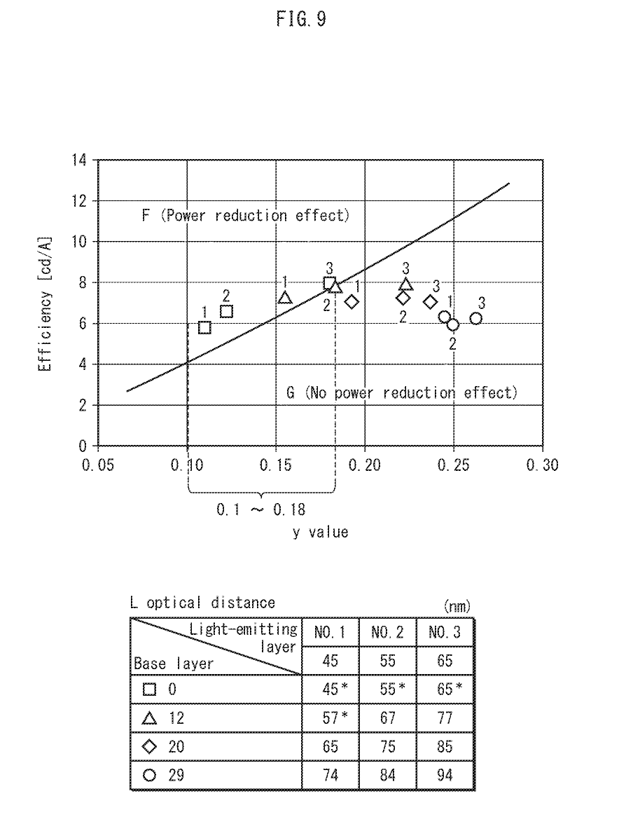

To test this, the optical distance LLB in the second blue sub-pixels 21LB was changed and a relationship between color of light emitted from sub-pixels and light emission efficiency of the sub-pixels was investigated. FIG. 9 shows the relationship between color of light emitted from sub-pixels of the second blue sub-pixels 21LB and light emission efficiency of the sub-pixels. Each plot shows an experimental result when the optical distance LLB was changed in a range from 45 nm to 94 nm. A configuration was used in which film thickness of the second blue organic light-emitting layers 17LB was varied from 45 nm to 65 nm. Film thicknesses of 45 nm, 55 nm, and 65 nm are No. 1, No. 2, and No. 3, respectively, and these numbers are indicated next to each plot on the graph. In addition, film thickness of the base layer 13 was varied from 0 nm (no base layer 13) to 29 nm. Film thickness of the base layer 13 is indicated by shape of each plot on the graph. Thus, as shown in the matrix in FIG. 9, the optical distance LLB was varied from 45 nm to 94 nm. The curved line on the graph is a reference curve indicating an efficiency required to be equivalent to power consumption in an IEC video standard, while a y value of CIE chromaticity of light emitted from the second blue sub-pixels 21LB is varied.

As shown in FIG. 9, as the optical distance LLB is increased from 45 nm to 94 nm, a y value of a color of light emitted from the second blue sub-pixels 21LB increases. Further, in a range of y values equal to or less than 0.18, light emission efficiency is higher than the reference curve (region F), which indicates a relationship between y value and light emission efficiency, and when y values increase over 0.18, light emission efficiency is lower than the reference curve (region G).

That is, when the optical distance LLB is from 45 nm to 65 nm and the y value of light blue light emitted from the second blue sub-pixels 21LB is 0.18 or less (indicated by an asterisk in FIG. 9), even when light emission efficiency of the second blue sub-pixels 21LB is set relatively low, it is higher than the reference curve. In other words, in a direction perpendicular to the top surfaces 17a of the second blue organic light-emitting layers 17LB and the second pixel electrodes 12LB, when a distance between the top surfaces 17a of the second blue organic light-emitting layers 17LB and the second pixel electrodes 12LB is from 45 nm to 65 nm, even when light emission efficiency of the second blue sub-pixels 21LB is set relatively low, it is higher than the reference curve. Thus, for reasons of ensuring a color reproduction range, a y value of dark blue light emitted from the first blue sub-pixels 21DB is preferably 0.06, and at greatest less than 0.1, and a y value of light blue light emitted from the second blue sub-pixels 21LB is preferably from 0.1 to 0.18. Within these ranges, a power consumption reduction effect can be achieved when using the second blue sub-pixels 21LB in the panel 10.

Further, because the y value of dark blue light emitted from the first blue sub-pixels is less than 0.1 and the y value of light blue light emitted from the second blue sub-pixels is from 0.1 to 0.18, when the base layer 13 is not used or has a thickness of only a few nanometers, thickness of the first blue organic light-emitting layers 17DB is preferably less than 45 nm and thickness of the second blue organic light-emitting layers 17LB is preferably from 45 nm to 65 nm.

(2) Improving Color Purity and Light Emission Efficiency when Using Filter

The panel 10 may be configured to include the first blue filters 24DB above the opposing electrode 18 in the first blue sub-pixels 21DB, which lower a y value of CIE chromaticity of blue light emitted from the first blue organic light-emitting layers 17DB in the first blue sub-pixels 21DB. According to this configuration, in the first blue sub-pixels 21DB, dark blue light emitted from the first blue organic light-emitting layers 17DB is emitted towards the first blue filters 24DB, and dark blue light emitted towards the first blue filters 24DB has color components other than dark blue absorbed at the first blue filters 24DB to increase color purity and be emitted upwards as dark blue light. As a result, color purity of dark blue light emitted from the first blue organic light-emitting layers 17DB can be increased.

Further, the panel 10 may be configured to include the second blue filters 24LB above the opposing electrode 18 in the second blue sub-pixels 21LB, which have a higher transmittance in a wavelength range from 300 nm to 800 nm than the first blue filters 24DB. In this case, for wavelengths 300 nm to 800 nm, the transmission ratio of the first blue filters 24DB is preferably 0.5 or less and the transmission ratio of the second blue filters 24LB is preferably 0.7 or greater. According to this configuration, in the second blue sub-pixels 21LB, light blue light emitted from the second blue organic light-emitting layers 17B is emitted towards the second blue filters 24LB, and light blue light emitted towards the second blue filters 24LB has color components other than light blue absorbed at the second blue filters 24LB to increase color purity and be emitted upwards as light blue light. As a result, color purity of light blue light emitted from the second blue organic light-emitting layers 17LB can be increased.

Thus, according to the panel 10, a color of light emitted upwards from the first blue filters 24DB in the first blue sub-pixels 21DB is characterized by a smaller y value of CIE chromaticity than a color of light emitted upwards from the second blue filters 24LB in the second blue sub-pixels 21LB. More specifically, light emitted upwards from the first blue filters 24DB in the first blue sub-pixels 21DB has a y value of CIE chromaticity less than 0.1, and light emitted upwards from the second blue filters 24LB in the second blue sub-pixels 21DB has a y value of CIE chromaticity from 0.1 to 0.18.

Further, according to the panel 10, colors of light emitted from the first blue organic light-emitting layers 17DB and the second blue organic light-emitting layers 17LB are different and therefore, when compared to a configuration in which both types of light-emitting layer emit the same color of light, amounts of light absorbed by the first blue filters 24DB and the second blue filters 24LB are decreased and light emission efficiency of sub-pixels is improved.

### 4. Drive Method of Panel 10 in Display Device 1

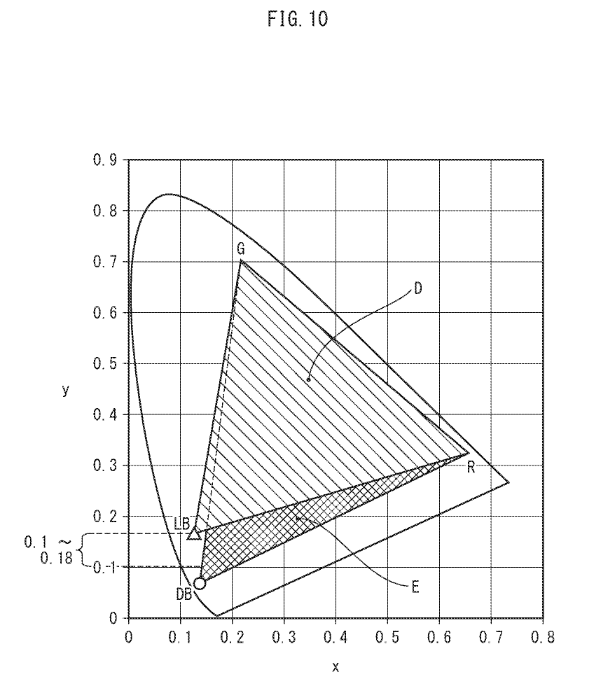

A configuration of the panel 10 described above is driven as follows in the display device 1. FIG. 10 shows color reproduction ranges of the display device 1 in a CIE chromaticity diagram. For example, in the chromaticity coordinate system shown in FIG. 10, in a display range that can be represented by, among colors of light emitted from the four types of the sub-pixels 21, red light emitted from the red sub-pixels 21R, green light emitted from the green sub-pixels 21G, and light blue light emitted from the second blue sub-pixels 21LB (hatched portion of FIG. 10), display is performed without using the first blue sub-pixels 21DB and only driving the three types of the sub-pixels 21. Further, in a display range that cannot be represented without using dark blue light emitted from the first blue sub-pixels 21DB (crosshatched portion E of FIG. 10), display is performed without using light blue light emitted from the second blue sub-pixels 21LB and only driving the red sub-pixels 21R, the green sub-pixels 21G, and the first blue sub-pixels 21DB.

### 5. Effects

As described above, the panel 10 pertaining to the embodiment has a plurality of the pixels 23 that include the red sub-pixels 21R, the green sub-pixels 21G, the first blue sub-pixels 21DB that emit dark blue light, and the second blue sub-pixels 21LB that emit light blue light; the first blue pixel electrodes 12DB and the first blue organic light-emitting layers 17DB layered above the substrate in regions of the first blue sub-pixels 21DB; and the second blue pixel electrodes 12LB and the second blue organic light-emitting layers 17LB layered above the substrate in regions of the second blue sub-pixels 21LB. The first blue light-emitting layers 17DB and the second blue light-emitting layers 17LB are made from the same material, and in a direction perpendicular to the top plane of the substrate, the distance between the top surfaces of the first blue organic light-emitting layers 17DB and the top surfaces of the first blue pixel electrodes 12DB is less than a distance between the top surfaces of the second blue organic light-emitting layers 17LB and the top surfaces of the second blue pixel electrodes 12LB. Thus, according to the panel 10, in the second blue sub-pixels 21LB that emit light blue light that has a high y value, a difference in optical path length between direct light and reflected light emitted from the organic light-emitting layers is different to that of the first blue sub-pixels 21DB that emit dark blue light, and therefore colors of light emitted from the organic light-emitting layers of both types of sub-pixel are different.

Thus, light extraction efficiency of the second blue sub-pixels 21LB can be improved, and light emission efficiency can be improved when compared to conventional technology. Further, reduced current is possible due to the improvement in light emission efficiency, increasing luminance half-life of the second blue sub-pixels 21LB. As a result, drive time power consumption reduction in the second blue sub-pixels 21DB accompanies the increase in light emission efficiency and life of the organic EL element can be increased.

Further, in the display device 1, an additional level of control of power consumption is possible beyond that of conventional technology by displaying images by controlling the first blue sub-pixels 21DB that emit dark blue light and the second blue sub-pixels 21LB that emit light blue light of a higher light emission efficiency than the dark blue light. For example, when outputting an image that does not require dark blue light, the image can be displayed by causing only the second blue sub-pixels 21LB to emit light blue light that has a high light emission efficiency. Further, the second blue sub-pixels 21LB have a longer luminance half-life than the first blue sub-pixels 21DB, and therefore increasing a usage ratio of the second blue sub-pixels 21LB can increase life of the display device 1.

Further, according to the display device 1, dark blue light emitted from the first blue sub-pixels and light blue light emitted from the second blue sub-pixels are used separately according to an image to be displayed, and therefore overall color purity of emitted blue light is improved and color reproduction range is increased.

### Modifications

The panel pertaining to an aspect of the present invention has been described according to Embodiment 1, but the present invention is not limited to the embodiment described, aside from essential characteristic elements thereof. For example, embodiments that would occur to a person having ordinary skill in the art modifying Embodiment 1, and embodiments implemented by any combination of element and function of Embodiment 1 that does not depart from the scope of the present invention are included in the present invention. The following describes modifications of the panel 10 as examples of such embodiments.

### 1. Configuration without Filters

According to the panel 10 pertaining to Embodiment 1, the first blue filters 24DB that are dark blue filters are above the first blue intervals 20DB in which are the first blue sub-pixels 21DB, and the second blue filters 24LB that are light blue filters are above the second blue intervals 20LB in which are the second blue sub-pixels 21LB. However, in the example of the panel 10, configurations may be adopted in which only dark blue filters are provided over the first blue intervals 20DB in which are the first blue sub-pixels 21DB and the second blue filters 24LB are not provided over the second blue intervals 20LB in which are the second blue sub-pixels 21LB. In this case, as in Embodiment 1, because the y value of dark blue light emitted from the first blue sub-pixels is less than 0.1 and the y value of light blue light emitted from the second blue sub-pixels is from 0.1 to 0.18, when the base layer 13 is not used or has a thickness of only a few nanometers, thickness of the first blue organic light-emitting layers 17DB is preferably less than 45 nm and thickness of the second blue organic light-emitting layers 17LB is preferably from 45 nm to 65 nm. Thus, when compared to a case in which the second blue filters 24LB are provided over the second blue intervals 20LB, light emission efficiency of the second blue sub-pixels 21LB can be improved. As a result, power consumption of the panel 10 is further suppressed by control of display of the dark blue sub-pixels and light blue sub-pixels, further increasing luminance half-life of the second blue sub-pixels 21LB.

### 2. Configuration without Base Layer

The present invention is not limited to Embodiment 1. For example, a configuration may be used without using the base layer 13, which is a hole injection layer, in which only the light-emitting layers 17 exist between the pixel electrodes 12 and the opposing electrode 18. In this case, thickness of the first blue organic light-emitting layers 17DB is less than 45 nm and thickness of the second blue organic light-emitting layers 17LB is preferably from 45 nm to 65 nm. Thus, light emission efficiency of the second blue sub-pixels 21LB can be improved and life of the second blue sub-pixels 21LB can be improved.

Further, for example, configurations may include hole injection layers, hole transport layers, electron transport layers, or electron injection layers, a plurality of these layers, or all of these layers. Further, these layers need not all be organic compounds, and may be inorganic.

### 3. Other Modifications

According to Embodiment 1, three types of the pixels 21 are the red pixels 21R, the green pixels 21G, and the blue pixels 21B, but the present invention is not limited to this example. For example, there may be only one type of light-emitting layer, or four types of light-emitting layers may emit red, green, blue, and yellow light.

Further, according to Embodiment 1, the pixels 21 are arranged in a matrix, but the present invention is not limited to this example. For example, even when intervals of pixel regions are one pitch and adjacent ones of the pixel regions are shifted by a half pitch in the column direction, effects of the present invention are achieved. In high definition display panels, it is difficult to visually determine some shift in the column direction, and on a straight line of a certain width (or a zigzag pattern) even uneven film thickness appears to be regular. Accordingly, in such a case, luminance unevenness is suppressed in the zigzag pattern described above, improving display quality of the display panel.

Further, according to Embodiment 1, methods of forming the light-emitting layers 17 are wet film formation processes such as printing, spin coating, and inkjet methods, but the present invention is not limited to these examples. For example, dry film formation processes such as vacuum deposition, electron beam deposition, sputtering, reactive sputtering, ion plating, and vapor phase growth may be used.

Further, according to the panel 10 pertaining to Embodiment 1, the pixel electrodes 12 are disposed in all of the intervals 20, but the present invention is not limited to this configuration. For example, in order to form a bus bar, an interval of the intervals 20 need not have any of the pixel electrodes 12 formed therein.

Further, according to Embodiment 1, the panel 10 is a top-emission type, but a bottom-emission type can alternatively be used. In this case, each configuration is changed as appropriate.

Further, according to Embodiment 1, the panel 10 is configured as an active matrix, but the present invention is not limited to this example and may, for example, by a passive matrix. More specifically, elongate electrodes that extend parallel to the first banks and elongate electrodes that extend orthogonal to the first banks may be provided in plurality, sandwiching the light-emitting layers. When the elongate electrodes that extend orthogonal to the first banks are lower electrodes, a plurality of lower electrodes are arranged in each of the intervals in the direction of extension of the first banks with gaps therebetween, implementing an aspect of the present invention. In this case, each configuration is changed as appropriate. According to Embodiment 1, the substrate 11 has a TFT layer, but in cases such as the passive matrix described above the substrate 11 need not have the TFT layer.

### INDUSTRIAL APPLICABILITY

The organic EL display panel and organic EL display device pertaining to the present invention are applicable to a wide range of devices such as television sets, personal computers, and portable telephones, as well as various other electronic devices that have a display panel.

### REFERENCE SIGNS LIST

1 organic EL display device
10 organic EL display panel
11 substrate
12 pixel electrodes
13 base layer
14 second banks
16 first banks
17 light-emitting layers
18 opposing electrode
19 sealing layer
20 intervals
21 sub-pixels
22 inter-pixel regions
23 pixels
24 filters

1. An organic electroluminescence (EL) display panel in which a plurality of pixels are arranged in a matrix of rows and columns on a substrate, each pixel including a red sub-pixel that emits red light, a green sub-pixel that emits green light, a first blue sub-pixel that emits dark blue light, and a second blue sub-pixel that emits light blue light, the organic EL display panel comprising:
the substrate;
a first blue pixel electrode and a first blue organic light-emitting layer layered above the substrate in a region of the first blue sub-pixel; and
a second blue pixel electrode and a second blue organic light-emitting layer layered above the substrate in a region of the second blue sub-pixel, wherein
the first blue organic light-emitting layer and the second blue organic light-emitting layer are made from the same material, and
in a direction perpendicular to a top plane of the substrate, a distance between a top surface of the first blue organic light-emitting layer and a top surface of the first blue pixel electrode is less than a distance between a top surface of the second blue organic light-emitting layer and a top surface of the second blue pixel electrode.

2. The organic EL display panel of claim 1, wherein
thickness of the first blue organic light-emitting layer is less than thickness of the second blue organic light-emitting layer.

3. The organic EL display panel of claim 2, wherein
thickness of the first blue organic light-emitting layer is less than 45 nm and thickness of the second blue organic light-emitting layer is from 45 nm to 65 nm.

4. The organic EL display panel of claim 1, wherein
a y value of CIE chromaticity of light emitted from the first blue sub-pixel is less than a y value of CIE chromaticity of light emitted from the second blue sub-pixel.

5. The organic EL display panel of claim 1, wherein
a first filter that lowers a y value of CIE chromaticity of light emitted from the first blue organic light-emitting layer is disposed above the first blue organic light-emitting layer.

6. The organic EL display panel of claim 5, wherein
a second filter that has a higher transmittance of light in a wavelength range from 600 nm to 800 nm than the first filter is disposed above the second blue organic light-emitting layer.

7. The organic EL display panel of claim 6, wherein
transmittance of light in a wavelength range from 300 nm to 800 nm by the first filter is 0.5 or less and transmittance of light in the wavelength range from 300 nm to 800 nm by the second filter is 0.7 or greater.

8. The organic EL display panel of claim 6, wherein
a y value of CIE chromaticity of light emitted upwards from the first filter in the first blue sub-pixel is less than a y value of CIE chromaticity of light emitted upwards from the second filter in the second blue sub-pixel.

9. The organic EL display panel of claim 6, wherein
a y value of CIE chromaticity of light emitted upwards from the first filter in the first blue sub-pixel is less than 0.1 and a y value of CIE chromaticity of light emitted upwards from the second filter in the second blue sub-pixel is from 0.1 to 0.18.

10. A method of manufacturing an organic electroluminescence (EL) display panel in which a plurality of pixels are arranged in a matrix of rows and columns, each pixel including a red sub-pixel that emits red light, a green sub-pixel that emits green light, a first blue sub-pixel that emits dark blue light, and a second blue sub-pixel that emits light blue light, the method comprising:
a process of forming a first blue pixel electrode and a first blue organic light-emitting layer layered in this order above the substrate in a region of the first blue sub-pixel, and forming a second blue pixel electrode and a second blue organic light-emitting layer layered in this order above the substrate in a region of the second blue sub-pixel, wherein
in the process of forming the first blue organic light-emitting layer and the second blue organic light-emitting layer, in a direction perpendicular to the plane of the substrate, a distance between a top surface of the first blue organic light-emitting layer and a top surface of the first blue pixel electrode is made to be less than a distance between a top surface of the second blue organic light-emitting layer and a top surface of the second blue pixel electrode layer.
